(19) United States
(12) Patent Application Publication
(10) Pub. No.: US 2008/0080722 A1
(43) Pub. Date: Apr. 3, 2008

(54) LOUDNESS CONTROLLER WITH REMOTE AND LOCAL CONTROL

(76) Inventors: Tim J. Carroll, Lancaster, PA (US); Leif Claesson, Lancaster, PA (US)

Correspondence Address: DUANE MORRIS LLP;PATENT DEPARTMENT, 1540 BROADWAY, NEW YORK, NY, 10036-4086, US

(21) Appl. No.: 11/861,825

(22) Filed: Sep. 26, 2007

Related U.S. Application Data
(60) Provisional application No. 60/827,464, filed on Sep. 29, 2006.

(51) Int. Cl. H03G 3/00

(52) U.S. Cl. 381/109

(57) ABSTRACT

A system and method associated with a recipient's audio equipment for maintaining desired loudness of a received audio signal is disclosed. The system includes a receiver device for receiving a broadcasted input signal and for transforming the input signal into a transport stream. The input signal and said transport stream have a non-processed audio signal component which contains its original dynamic range. A loudness controller is incorporated in the system so that it for receives the non-processed audio signal component of said transport stream and performs a process of dynamic range control on the non-processed audio signal component. A data signal containing settings for configuring the loudness controller is used for selectively controlling the operations of the loudness controller. The data signal allows external audio metadata to be accepted and used for control of the loudness controller. Alternatively, the loudness controller accepts external user input by the recipient to modify or tailor this consumer-side loudness controller to the taste or needs of the recipient. The loudness controller may also be bypassed to allow the original audio to pass unmodified.

### CROSS REFERENCE TO RELATED APPLICATION

This application claims priority to U.S. provisional Patent Application Ser. No. 60/827,464, filed Sep. 29, 2006, which is hereby incorporated by reference.

### BACKGROUND OF THE INVENTION

This invention relates generally to the field of broadcast and consumer audio. More particularly, the invention described herein is directed to a system that maintains an even loudness of sound in response to parameters that are remotely controlled by broadcasters or program producers, with the ability for the consumer to accept, change, or completely ignore this data, or even to revert to automatic local control in the event of the absence of remote control. While this function can work in both professional and non-professional consumer applications, it is primarily intended to operate within non-professional consumer equipment such as television sets, receivers, DVD players and or recorders, cable set top box receivers, satellite set top box receivers, iPod or similar portable audio devices, video tape recorders, or any type of equipment that reproduces audio. An aspect of the invention is that the high quality, broadcast-style dynamic range processing occurs completely within the non-professional consumer equipment, allowing audio of any type or loudness to be transmitted and any correction to be measured and applied locally.

A vast majority of non-professional consumers (hereinafter referred to simply as “consumers”) and professionals (consumers and professionals may be referred to herein collectively as “recipients” and sometimes individually as a “recipient”) recognize the common problem of loudness shifts in programs, and have relied upon techniques that attempt to control loudness by adjusting programs prior to transmitting them to consumers or professionals. This type of audio processing function is commonly found in professional broadcast equipment manufactured by companies such as Orban, Omnia, and Linear Acoustic and in the past has been relegated to the broadcasters location due to the high degree of sophistication and therefore processing power required to properly effect loudness control with a minimum of side effects. This “broadcast-side” approach can work quite well for a given single program channel, however there are several major problems that the broadcast-side approach cannot solve and which the current invention addresses.

The first problem with the broadcast-side approach is that every broadcast channel delivered to consumers requires precisely the same processing equipment adjusted in precisely the same manner, otherwise there will very likely be loudness shifts when switching between broadcast channels.

Another problem with the broadcast-side approach is that modern program delivery is varied and may follow many different paths before arriving at the consumer. Other programming, such as commercials, may be inserted after the broadcaster (and their loudness controller) and before the consumer thus creating a mismatch in loudness.

Still another problem with the broadcast-side approach is that all programming will have had its dynamic range limited in order to control loudness, thereby affecting the intentions of the original program producer and delivering a program created for the highest quality playback but modified to be acceptable in the lowest quality reproduction system.

An approach for solving the problem of loudness shifts involves performing some sort of control at the “consumer-side.” Two separate but similar methods that attempt to solve the problem of loudness shifts from the consumer-side can be found in patent literature. The first is found in U.S. Pat. No. 5,631,714 (“Apparatus for Automatically Adjusting the Mean Sound Level of a Television Receiver”) where a simple wide-band limiter is inserted into the program audio in an effort to reduce the peak to average ratio of audio applied to it, thereby in effect controlling loudness. This system has the advantage that it is located just before the audio is output to the consumer, and could in theory process a plurality of audio sources applied to it in addition to the television audio signal thereby producing an even loudness whether the consumer chooses to view a DVD, listen to the radio, or watch television.

In practice however, this approach lacks the critically important ability to accept input from program producers who might wish to modify the characteristics of the system on a program by program basis. Further, and more importantly, as has been described by Orban in at least one patent (U.S. Pat. No. 4,249,042, entitled “Multiband Cross-Coupled Compressor with Overshoot Protection Circuit”), and as persons skilled in the art will recognize, wideband control of audio loudness produces objectionable side effects, sometimes called intermodulation distortion, which can cause programs to be unintentionally reduced in loudness to the point of being too soft, and can negatively affect dialog intelligibility. The system described in U.S. Pat. No. 5,631,714 has not been found in any known consumer or professional applications and this is likely due to its technical and artistic limitations.

The second approach to this problem is described in the Advanced Television System Committee standard A/52 developed by Dolby Laboratories, which is hereby incorporated by reference. This standard describes a system where audio is measured at the point of transmission and gain control values are generated and passed along as side channel information, better known as “audio metadata.” These values accompany audio that remains unprocessed until it reaches the final decoder where the metadata values are applied by default, and can also be adjusted by the consumer to be applied less or not at all, thereby reproducing the original audio. This system is included in the AC-3 audio coding system from Dolby Laboratories and is standardized in ATSC and DVB television standards, and can be applied to any audio coding scheme. In theory, it allows program producers to generate dynamic range control parameters individually for every program.

In practice, there are several shortcomings of this approach that can actually lead to the exacerbation of loudness problems. First, the audio metadata system relies upon the program producer to set the values correctly. If not set correctly, either intentionally or accidentally, consumers will be presented with sound that may be intentionally or accidentally different in loudness from other programs and or other program channels. As each producer has different taste, variations can and do enter into the process and affect consistency. Further, if the audio metadata is missing due to channel error or intentional omission, the system will have no ability to control loudness. This happens on an all too regular basis within broadcast facilities today worldwide and is leading to what is arguably the worst outbreak of loudness problems in the history of television broadcasting.

Another problem with the audio metadata system included in AC-3 is that it is wideband in nature, and as has been described by Orban, and as anyone skilled in the art will recognize, wideband control of audio loudness produces objectionable side effects, sometimes called intermodulation distortion, can cause programs to be unintentionally reduced in loudness to the point of being too soft, and can negatively affect dialog intelligibility. A further problem is that due to the fact that the loudness controls are generated at the point of transmission and only applied at the consumer side, they are only useful for program channels that have metadata and cannot be applied to other sources that consumers may wish to reproduce from the same system.

### SUMMARY OF THE INVENTION

The system and method of the present invention combines the attractive idea of transmitting audio, primarily to consumers, in a non-processed manner whereby the original loudness and dynamic range are not affected. A very efficient and sophisticated multiband gain control system is then located in the consumer equipment to control loudness at the consumer side and audio metadata is accepted to allow optimization by program producers. Importantly, the system is capable of falling back to a set of generally applicable values in case this extra data is missing or damaged, and uniquely can be modified or even completely shut off in cases where consumers desire more or even the full original audio dynamic range. Importantly, as the measurement and generation of control signals is done locally, all sources can benefit from the inclusion of this process, not just audio streams that contain audio metadata.

In one embodiment of the invention, an audio system is associated with a recipient's audio equipment for maintaining desired loudness of a received audio signal. The system includes a receiver device for receiving a broadcasted input signal and for transforming the input signal into a transport stream. The input signal and the transport stream each have a non-processed audio signal component containing its original dynamic range. A loudness controller for receiving the non-processed audio signal component of the transport stream is incorporated in the recipient's audio equipment for performing a process of dynamic range control on the non-processed audio signal component. Means are also provided for selectively controlling the operation of the loudness controller.

In a particular aspect of the invention, the means for controlling the loudness controller is a data input that contains settings which are determined by an audio generator thereby configuring the loudness controller in a manner determined by the audio generator.

In another aspect of the invention, the means for controlling the loudness controller is a data input that contains settings which are determined by recipient so that the loudness controller is configured in a manner determined by the recipient.

In a further aspect of the invention, the recipient can by-pass the loudness controller thus allowing the original dynamic range of the non-processed signal to continue through the system.

Yet another aspect of the invention is that the loudness controller is a multiple frequency band loudness controller with between two and five bands that includes automatic gain control, limiters and distortion controlled peak limiters.

In a method of the invention, a desired loudness of a recipient's received audio is maintained by receiving at a receiving device in the recipient's equipment a broadcasted input signal and transforming the input signal into a transport stream. The input signal and said transport stream each have a non-processed audio signal component containing its original dynamic range. The loudness controller receives the non-processed audio signal component of the transport stream and performs a process of dynamic range control on the non-processed audio signal. The loudness controller is selectively controlled by the use of data signals supplied to the loudness controller.

### BRIEF DESCRIPTION OF THE DRAWINGS

FIG. 1 is a block diagram illustrating a system incorporating the present invention in which loudness control is located inside the recipient's equipment;

FIG. 2 is a block diagram illustrating an aspect of the invention shown in FIG. 1;

FIG. 3 is a block diagram illustrating another feature of the invention shown in FIG. 1;

FIG. 4 is a block diagram also illustrating another feature of the invention shown in FIG. 1;

FIG. 5 is a block diagram illustrating a home theater type consumer receiver having another aspect of the present invention;

FIG. 6 is a block diagram illustrating another aspect of the invention shown in FIG. 5;

FIG. 7 is a block diagram illustrating yet another aspect of the invention shown in FIG. 5;

FIG. 8 is a block diagram illustrating a general multi-section, multiband loudness controller according to an aspect of the invention;

FIG. 9 is a block diagram illustrating the general multi-section, multiband loudness controller of FIG. 8 according to another aspect of the invention;

FIG. 10 is a block diagram illustrating the general multi-section, multiband loudness controller of FIG. 8 according to another aspect of the invention;

FIG. 11 is a block diagram illustrating the general multi-section, multiband loudness controller of FIG. 8 according to another aspect of the invention;

FIG. 12 is a block diagram illustrating an aspect of the invention whereby the automatic gain control is part of the audio decoder; and

FIG. 13 is a block diagram illustrating the aspect of the invention whereby the automatic gain control is part of the audio decoder having yet a further feature.

### DESCRIPTION OF EMBODIMENTS

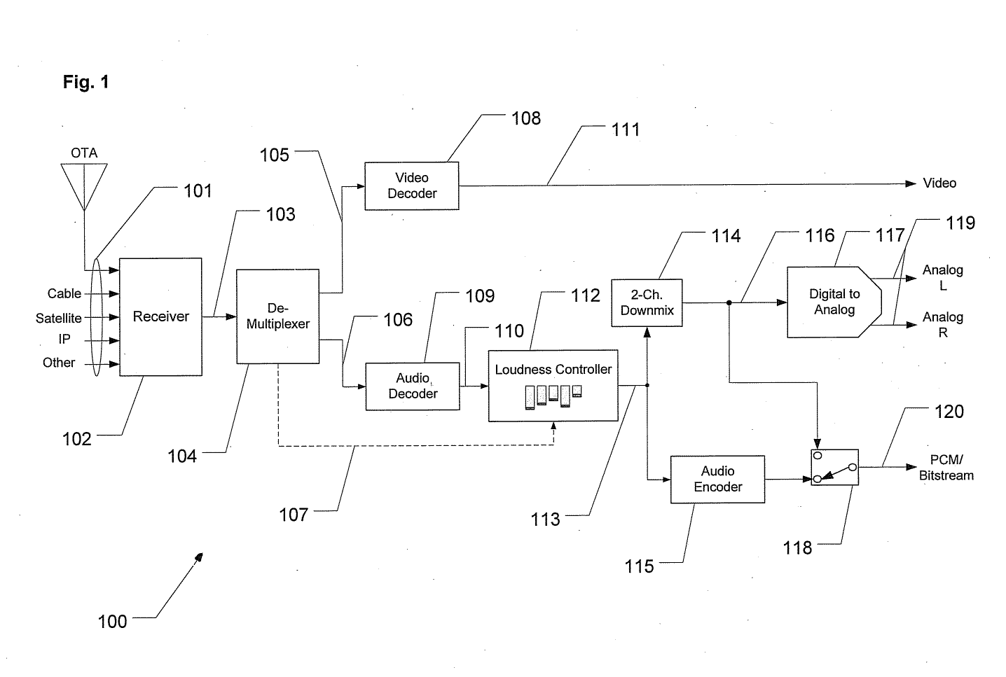

Referring now in more detail to the drawings, FIG. 1 is a general representation of a system capable of receiving an input signal 101, which includes an audio component, from any of several inputs including over-the-air (OTA), cable, satellite, Internet Protocol (IP), or any other source. The system 101 could, for example, be a consumer's television receiver or set top box. The system 101 has a receiver device 102 that transforms any of these inputs into a standard transport stream 103, one example being an MPEG compliant stream which is then fed to a de-multiplexer 104, the purpose of which is to split off several parallel streams from the serial input. These outputs may include video output 105, two-channel PCM audio or encoded audio signal 106 that may represent any number of encoded audio channels, but typically between two and 5.1, and data output 107.

The video and audio signals from the de-multiplexer 104 may be coded by the broadcaster as MPEG-2 for video, AC-3, Coherent Acoustics, MPEG, or some other format for the audio to provide these signals in an efficient manner. Specifications such as the U.S. ATSC and the European DVB standards describe these coding systems in greater detail. The video signal 105 may need to be decoded back to baseband video signal 111 by a video decoder 108. The audio signal 106 may need to be decoded by an audio decoder 109 back to one or more channels of baseband PCM digital audio signal 110 prior to output or further processing.

After this decoding by the audio decoder 109 the PCM digital audio signal can be applied to a multiband loudness controller 112 which has the purpose of raising the audio loudness of a quiet program to a predetermined target, or of lowering the audio loudness of a loud program to a predetermined target. This process is called dynamic range control and results in a signal that is neither too quiet nor too loud regardless of the loudness of the original signal.

The loudness controller 112 can be of any type, although multiple frequency bands are preferred, and contains automatic gain control, limiters, and distortion controlled peak limiters. The precise number of bands is based upon the available processing power, but a minimum of two bands is suggested to mitigate the negative side effects mentioned above found in wideband devices. Other details regarding the loudness controller will be described further below.

It can be seen that a data output 107 is also produced from the de-multiplexer 104 and can be applied to the loudness controller 112 in order to pass along instructions from the person that generates the audio portion, such as the broadcaster or the original program producer (the “audio generator”) to configure the loudness controller in a manner they have determined to be acceptable.

The one or more loudness controlled audio channels can then be split amongst two paths. One path applies the one or more loudness controlled PCM audio channels to an audio encoder 115, and the other path applies the PCM audio channels to a downmixer 114 whose purpose is to combine any number of input channels to form a two channel output. The PCM output of this downmixer is then split amongst a further two paths; one path in which the PCM audio is converted by a digital-to-analog converter 117 to analog signals which typically appear as “RCA” or Pin Jack connectors compatible with a wide variety of consumer equipment. The other path provides this loudness controlled, downmixed signal to one side of switch 120 which enables the selection of this PCM audio signal, or a re-encoded version of this signal produced by local audio encoder 115. This encoder 115 can be AC-3, Coherent Acoustics, MPEG, or any other type of encoder whose purpose is to supply a single bitstream to external consumer equipment through a single wire commonly known as S/PDIF or optical connection commonly known as TOSLINK.

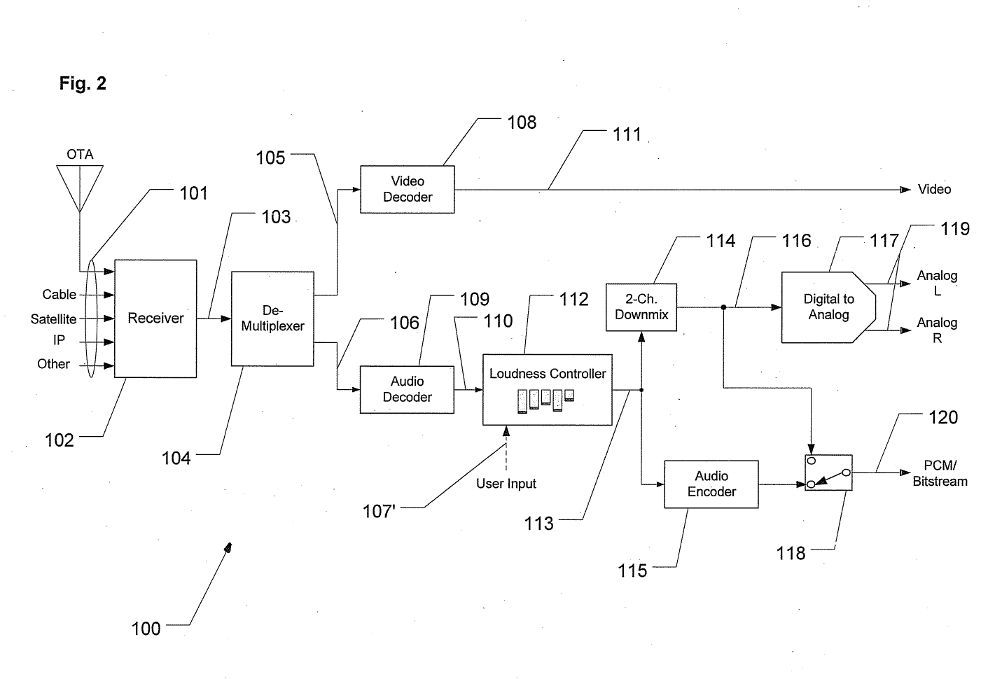

However, as can be seen in FIG. 2, data from the de-multiplexer 104 is not used at all and can be replaced by user input 107′ of preferred settings. Otherwise, FIG. 2 is identical to FIG. 1.

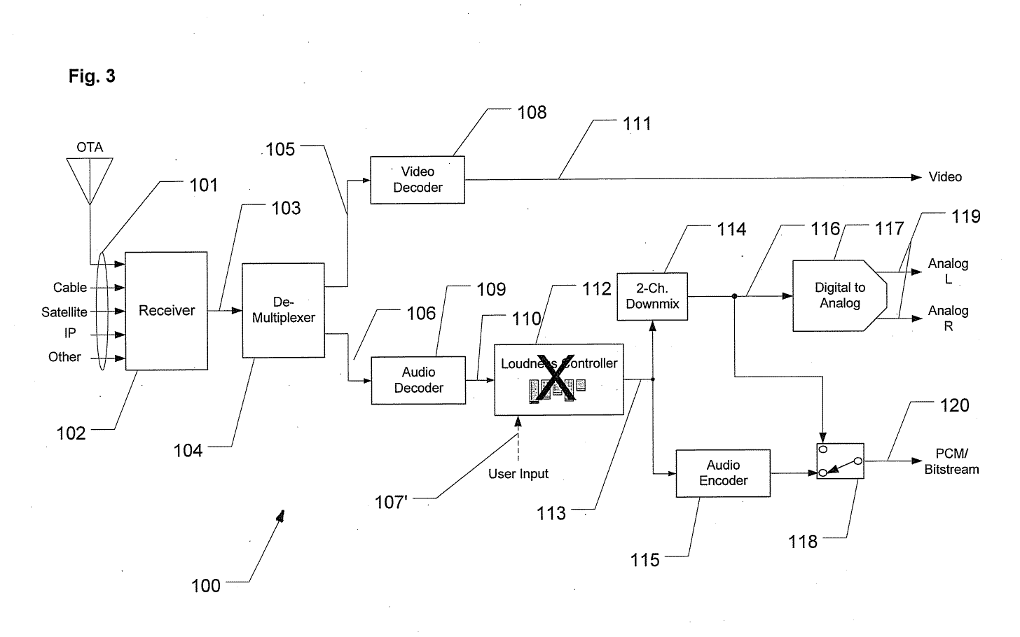

FIG. 3 shows exactly the same features as in FIG. 2 with the exception that it further illustrates that the consumer has decided to bypass the loudness controller completely via user input 107′, thereby restoring the original dynamic range to the audio signal and also possibly restoring any original loudness shifts.

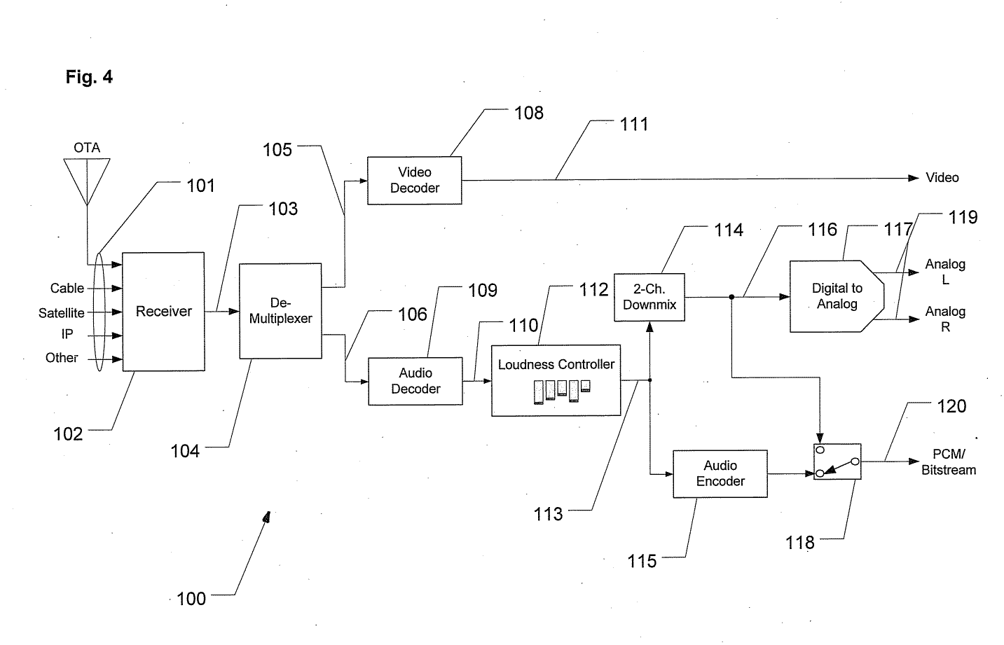

FIG. 4 is exactly the same as FIGS. 1 through 3 with the exception that there is no external data input, nor any user input data, and the loudness controller 112 therefore defaults to a standard degree of loudness control.

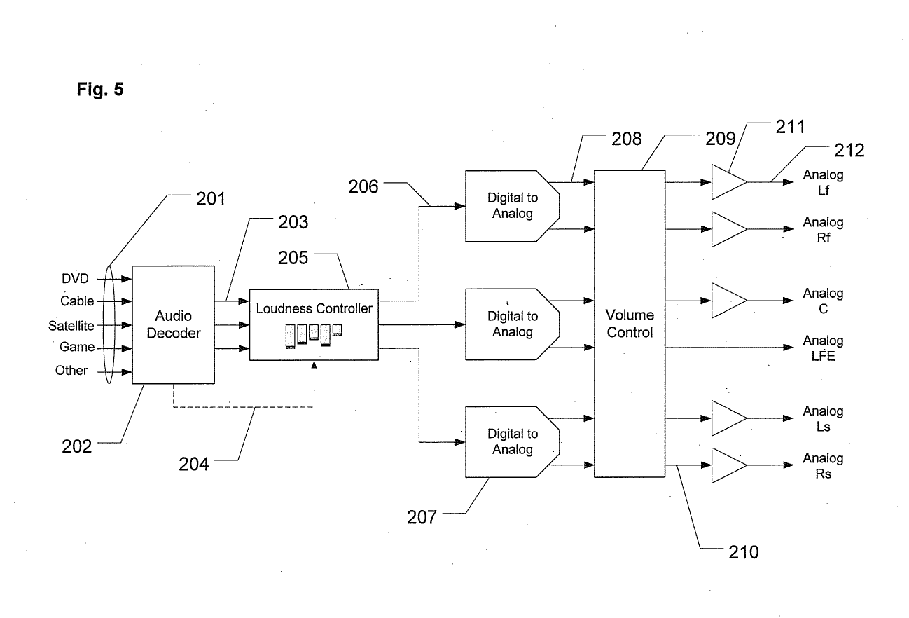

FIG. 5 generally represents a consumer audio/video receiver (“AVR”) as is commonly found in a home theater type system. Any number of input sources 201 may be applied to the AVR and are then decoded by an audio decoder 202 which may be of the AC-3, Coherent Acoustics, MPEG, or matrix (Dolby Pro Logic, Dolby PLII, DTS neo:6, SRS Circle Surround, etc.). The purpose of this audio decoder 202 is to decode any pre-encoded content into some number of PCM audio channels usually between one and 5.1, but any number is possible, or by a matrix decoder which has the ability to transform a two channel PCM signal into 2+n channels, with 4 and 5.1 being typical. The output of the audio decoder is shown as three separate PCM pairs for clarity, each representing two channels of PCM audio for a total of six channels.

These six PCM audio channels carried as three pairs can then be applied to loudness controller 205 which is the same type as described in connection with the system of FIGS. 1-4 above. It can be seen that a data signal 204 is also supplied from the audio decoder. This data signal can be any type of control data supplied by the content applied to the input of the decoder 202. This data is sometimes referred to as Metadata or Audio Metadata and serves the same purpose as the data shown in FIG. 1 above.

After decoding at audio decoder 202 the PCM audio can be applied to a multiband loudness controller 205 which has the purpose of raising the audio loudness of a quiet program to a predetermined target, or of lowering the audio loudness of a loud program to a predetermined target. This process is called dynamic range control and results in a signal that is neither too quiet nor too loud regardless of the loudness of the original signal.

The loudness controller can be of any type, although multiple frequency bands are preferred, and contains automatic gain control, limiters, and distortion controlled peak limiters. The precise number of bands is based upon the available processing power, but a minimum of two bands is suggested to mitigate the negative side effects mentioned above found in wideband devices. Other details regarding the loudness controller will be described further below.

The loudness controlled PCM audio 206 is now applied to three two-channel digital-to-analog converters 207, the main purposes of which are to transform the digital PCM signals into standard analog signals 208. These analog signals may then be applied to a standard volume control 209 whose output is determined by a consumer manually or remotely adjusting its position so as to produce a comfortable listening level. These consumer adjusted analog signals 210 can then be applied to internal power amplifiers 211 whose purpose is to amplify the analog signals to levels 212 appropriate for connection to loudspeakers. Note that the LFE channel does not normally contain an internal power amplifier due to the extra power it usually requires and as such the LFE channel amplification is usually performed externally.

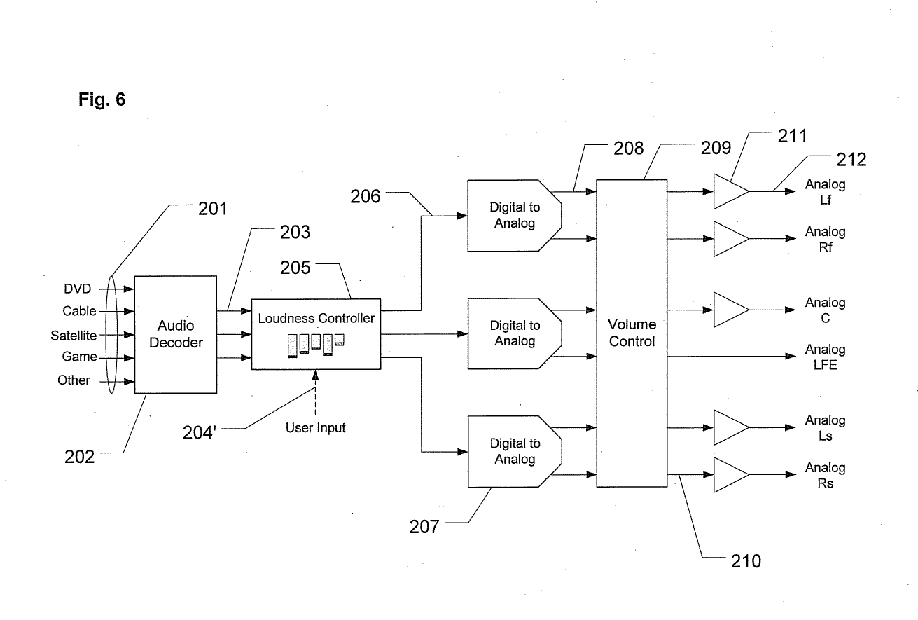

FIG. 6 is exactly the same as FIG. 5 with the exception that the data path into the loudness controller 205 has been replaced with user input 204′ where a consumer can choose to adjust the dynamic range to whatever degree they find most appropriate.

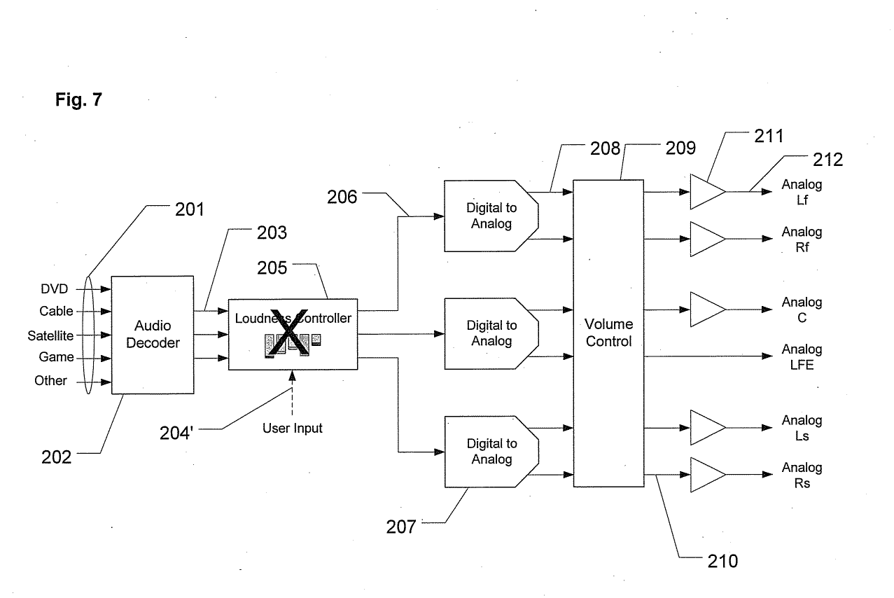

FIG. 7 is exactly the same as FIG. 6 with the exception that the consumer has decided to bypass the loudness controller completely via user input 204′, thereby restoring the original dynamic range to the audio signal and also possibly restoring any original loudness shifts.

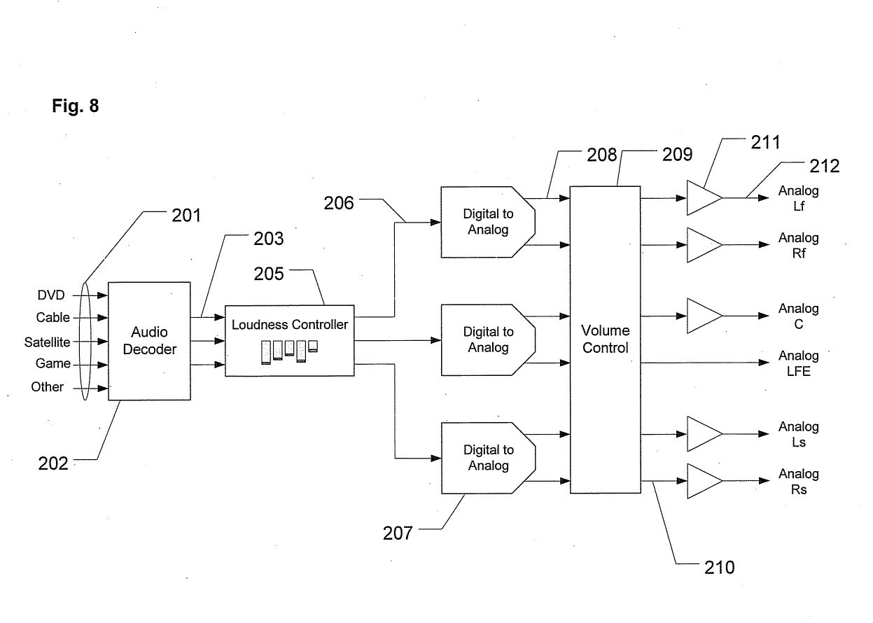

FIG. 8 is exactly the same as FIGS. 5 through 7 with the exception that there is no external data input, nor any user input data, and the loudness controller defaults to a standard degree of loudness control.

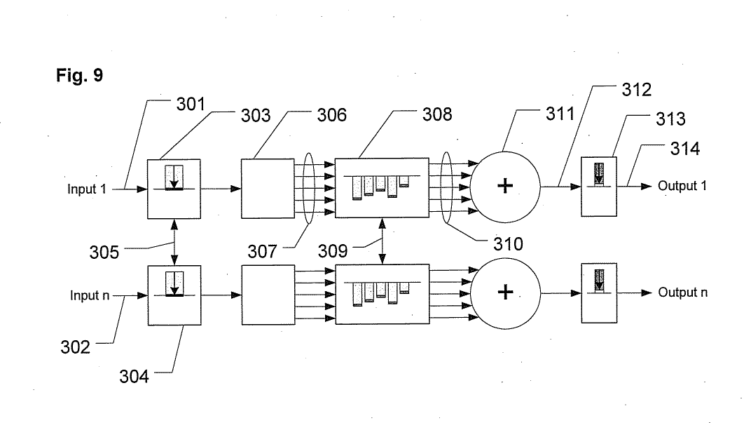

FIG. 9 shows a closer view of a general multi-section, multiband loudness controller. Some number of PCM audio channels 301 through 302 are applied to a first detector and gain controller called an Input Automatic Gain Control (or “AGC”) 303 whose properties are well known by those skilled in the art. The purpose of this input AGC is to slowly adjust the level of the incoming audio to gently smooth it out before applying it to the multiband crossover 306. Note that the input AGC actions are coupled by some means between all of the channels so that no one channel receives more of less control than any other channel, thereby preventing possible shifts in audio sound field imaging.

The multiband crossover serves the purpose of dividing up the audio signal into some number of sections or bands 307 which are then applied to individual multiband automatic gain controls (AGC) 308 for the purpose of minimizing audible artifacts that can be caused by large amounts of gain adjustment. Each band may have different timing characteristics whereby gain increases and decreases may occur more slowly for lower frequencies and more quickly for higher frequencies. These bands may also be coupled together by some means 309 so that no one band receives more or less control than another band as this might cause objectionable shifts in the spectral or frequency balance of the input signal. Further, each band of one channel may be coupled to each band of other channels to prevent one channel from receiving more or less control than any other channel, thereby preventing any possible shifts in audio sound field imaging.

The outputs 310 of the multiband automatic gain controls are then combined by a summer (or summing device) 311 to create a wideband signal 312 that is now loudness controlled on average.

This signal is then applied to a very fast detector and gain controller 313 whose characteristics are such that any peaks that remain in the loudness controlled signal are minimized. This is known as a peak limiter and it may actually be arranged in such a way that the control signal is developed slightly in advance of the audio reaching the gain control element so that it can be applied precisely when the peak is present. This technique is very well know to those skilled in the art as a look-ahead peak limiter and serves to minimize overshoots and audibility of its gain control actions.

The output 314 of this peak limiter now represents a loudness and overshoot controlled version of the input signal.

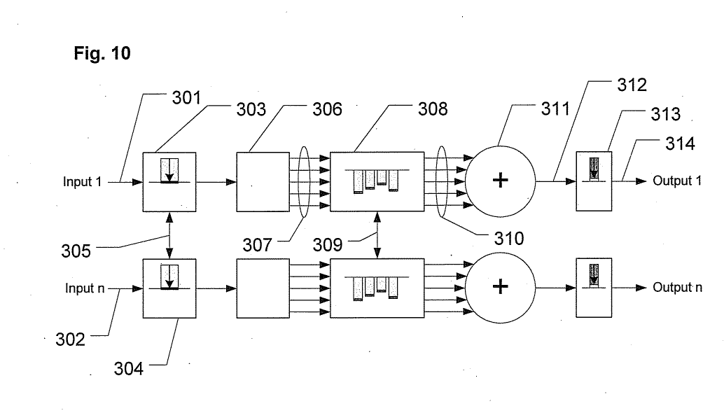

FIG. 10 is exactly the same as FIG. 9 with the exception that the number of bands produced by crossover 306 and acted upon by multiband AGC 308 has been reduced to four in order to conserve processing power. This arrangement will likely still provide the intended loudness control with inaudible side effects.

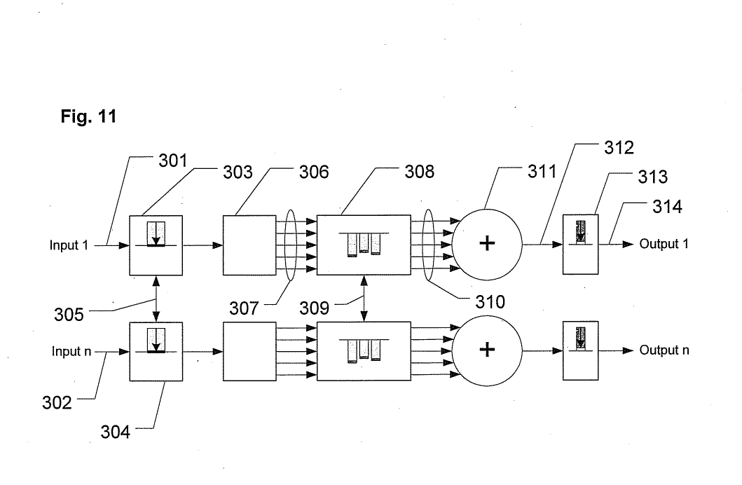

FIG. 11 is exactly the same as FIG. 10 with the exception that the number of bands produced by crossover 306 and acted upon by multiband AGC 308 has been reduced to three in order to conserve even more processing power. This arrangement may still provide the intended loudness control with minimal side effects.

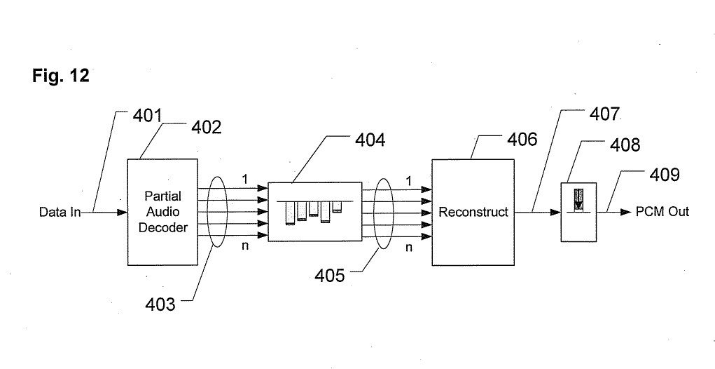

FIG. 12 shows an arrangement whereby the automatic gain control is actually a part of the audio decoder. As audio coding systems normally operate by breaking the audio signal up into some number of bands prior to encoding then reconstructing these bands to create a wide-bandwidth signal during the decoding process, it is possible to increase the efficiency of the gain controller by talking advantage of this arrangement. As the audio bands are already split as shown in 402, the need for a separate crossover is removed. Multiband gain control can be accomplished in the frequency domain 404 across as many bands or groups of bands as is necessary 403, and the gain controlled audio 405 reconstructed to form a wideband output. This signal can then be applied to a wideband peak limiter 408 as described above and then output as PCM audio 409.

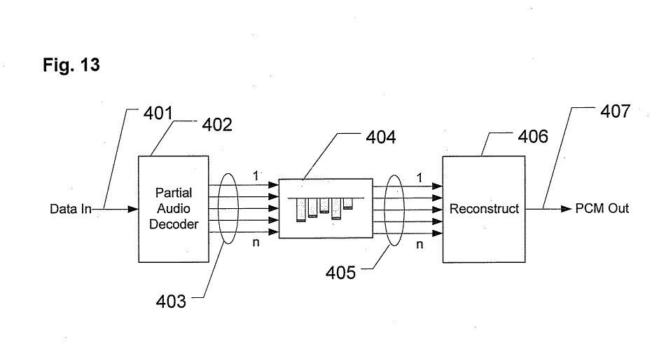

FIG. 13 is functionally the same as FIG. 12, but the peak limiting has also been made part of the frequency domain AGC processing 404 for a further savings in complexity. It is also possible that the peak limiting can be removed altogether in certain applications where very tight control is not necessary.

By way of brief summary, the invention is directed to a system that allows original broadcast audio to be accepted and delivered to consumers by some means with the original dynamic range and loudness unmodified; and with a structure that locates an efficient and sophisticated multiband loudness controller inside of consumer equipment intended to receive or otherwise accept external audio programs in the baseband or compressed domain. While this is of particular interest to equipment for the consumer market, the same is applicable to professional versions. The invention may include a structure that allows external audio metadata to be accepted and used for control of this consumer-side loudness controller. Structure may also be provided that accepts external user input to modify or tailor this consumer-side loudness controller to the taste or needs of the user. In addition, structure may be provided that: (i) accepts user control that effectively bypasses this consumer-side loudness controller to allow the original audio to pass unmodified; and/or (ii) that will still perform its basic function of loudness control with no need for audio metadata or user input, or any external control and operate in a self-contained manner; and/or (iii) a structure that can be scaled in efficiency by lowering the number of frequency bands across which loudness control is applied; and/or (iv) a structure that can be further optimized by locating its basic functions more fully inside existing structures such as audio decoders where some of the required sections, such as multiband filters or crossovers are already present and would not need to be duplicated, and operations can be performed in the frequency domain and then converted back to the time domain after decoding and loudness control have been performed; and/or (v) a structure that uses a loudness controller that may differ in precise design can operate in the time or frequency domain, or a combination of both; and/or (vi) a structure that can be implemented in the analog or digital domain, or a combination of both, with the preferred embodiment being in the digital domain.

Although the present invention has been described in detail with reference to certain preferred embodiments, it should be apparent that modifications and adaptations to those embodiments may occur to persons skilled in the art without departing from the spirit and scope of the present invention. Therefore, the breadth of the present invention should not be limited by the particular illustrative examples but rather by the following claims.

What is claimed is:

1. An audio system associated with a recipient's audio equipment for maintaining desired loudness of a received audio signal comprising:
a receiver device for receiving a broadcasted input signal and for transforming said input signal into a transport stream, said input signal and said transport stream having a non-processed audio signal component containing its original dynamic range;
a loudness controller for receiving said non-processed audio signal component of said transport stream and for performing a process of dynamic range control on said non-processed audio signal component; and
means for selectively controlling the operation of said loudness controller.

2. The system according to claim 1, wherein said means for selectively controlling the operation of said loudness controller is a data signal fed to said loudness controller, said data signal containing settings for configuring said loudness controller and thereby controlling its operation.

3. The system according to claim 2, wherein said data signal contains settings determined by an audio generator thereby configuring said loudness controller in a manner determined by said audio generator.

4. The system according to claim 2, wherein said data signal contains settings determined by said recipient thereby configuring said loudness controller in a manner determined by said recipient.

5. The system according to claim 2, wherein no data signal is provided to said loudness controller thus allowing said loudness controller to leave the original dynamic range of said non-processed signal in place.

6. The system according to claim 1, wherein said loudness controller is a multiple frequency band loudness controller.

7. The system according to claim 6, wherein said multiple frequency band loudness controller may include automatic gain control, limiters and/or distortion controlled peak limiters.

8. The system according to claim 6, wherein said multiple frequency band loudness controller has a minimum of two bands.

9. The system according to claim 2, further comprising a de-multiplexer connected to said receiver device for splitting said transport stream into parallel streams, at least one of which is said audio signal component.

10. The system according to claim 9, wherein said data signal is output from said de-multiplexer and fed into said loudness controller for providing instructions to said loudness controller to configure the operation of said loudness controller.

11. The system according to claim 10, wherein said audio signal component is an encoded audio signal component.

12. The system according to claim 11, further comprising an audio decoder connected to said de-multiplexer for decoding said encoded audio signal component and for transmitting said decoded audio signal component to said loudness controller.

13. The system according to claim 1, wherein said audio signal component is an encoded audio signal component and wherein said receiver device is an audio decoder for decoding any pre-encoded content in said audio signal component into a plurality of PCM audio channels.

14. The system according to claim 13, wherein the output of said audio decoder is a plurality of PCM pairs, each said pair representing two channels of PCM audio signals, said output PCM audio being provided to said loudness controller to thereby produce loudness controlled PCM audio signals.

15. The system according to claim 14, further comprising a digital-to-analog converter for converting each of said PCM audio signals into analog signals, and a volume controller for receiving said analog signals and for producing a signal having a desired level of volume that can be fed to a loudspeaker, said volume controller being operable by said recipient.

16. The system according to claim 14, wherein said loudness controller includes an input automatic gain control for receiving and adjusting the level of the PCM audio signals, a multi-band crossover for dividing said PCM audio signal into a plurality of bands, and a plurality of multiband automatic gain controls for receiving said PCM audio signals from said crossover and for minimizing audible artifacts caused by gain adjustment.

17. The system according to claim 16, wherein the bands of said multiband automatic gain controls may be coupled together so that no one band receives more or less control than another band.

18. The system according to claim 17, further comprising a summing device for receiving the output of said multiband automatic gain controls and for creating a wideband signal that is loudness controlled.

19. The system according to claim 17, wherein there are between two and five of said bands.

20. A method for maintaining desired loudness of a received audio signal received by a recipient's audio equipment comprising:
receiving at a receiving device a broadcasted input signal and transforming said input signal into a transport stream, said input signal and said transport stream having a non-processed audio signal component containing its original dynamic range;
receiving said non-processed audio signal component of said transport stream at a loudness controller for performing a process of dynamic range control on said non-processed audio signal component; and
selectively controlling the operation of said loudness controller.

21. The method according to claim 20, wherein said step of selectively controlling the operation of said loudness controller comprises feeding a data signal fed to said loudness controller, said data signal containing settings for configuring said loudness controller and thereby controlling its operation.

22. The method according to claim 21, wherein said data signal contains settings determined by the audio generator or by the recipient thereby configuring said loudness controller in a manner determined by the party determining said settings.

23. The method according to claim 20, wherein said loudness controller is a multiple frequency band loudness controller, there being between two and five bands.

24. The method according to claim 23, wherein said multiple frequency band loudness controller includes automatic gain control, limiters and distortion controlled peak limiters.

25. The method according to claim 20, wherein said audio signal component is an encoded audio signal component.

26. The method according to claim 25, further comprising decoding said encoded audio signal component by an audio decoder and outputting said decoded audio signal component to said loudness controller.

27. The method according to claim 26, wherein the output of said audio decoder is a plurality of PCM pairs, each said pair representing two channels of PCM audio signals, said output PCM audio being provided to said loudness controller to thereby produce loudness controlled PCM audio signals.

28. The method according to claim 27, further comprising converting each of said PCM audio signals into analog signals, and controlling the volume of said analog signals thereby producing a signal having a desired level of volume, that can be fed to a loudspeaker, said step of controlling the volume of said analog signals being performed by said recipient.

29. The method according to claim 14, further comprising the step adjusting the level of the PCM audio signals by an automatic gain control.

30. The method according to claim 29 wherein said automatic gain control is part of said loudness controller.

31. The method according to claim 29 wherein said automatic gain control is part of said audio decoder.

32. The method according to claim 29, further comprising the step of summing the output of said multiband automatic gain controls and creating a wideband signal that is loudness controlled.
